(19) United States
(12) Patent Application Publication
(10) Pub. No.: US 2026/0213133 A1
(43) Pub. Date: Jul. 23, 2026

(54) PLASMA PROCESSING METHOD AND PLASMA PROCESSING APPARATUS

(71) Applicant: Tokyo Electron Limited, Tokyo (JP)

(72) Inventor: Takahiro YONEZAWA, Miyagi (JP)

(73) Assignee: Tokyo Electron Limited, Tokyo (JP)

(21) Appl. No.: 19/644,575

(22) Filed: Apr. 10, 2026

Related U.S. Application Data
(63) Continuation of application No. PCT/JP2024/036324, filed on Oct. 10, 2024.

(30) Foreign Application Priority Data
Oct. 24, 2023 (JP) 2023-182378

(51) Int. Cl. H01J 37/32

(52) U.S. Cl. CPC H01J 37/3244; H01J 2237/332; H01J 2237/334

(57) ABSTRACT

A plasma processing method includes (a) providing a substrate on a substrate support in a chamber, the substrate having an underlying film, a first film on the underlying film, and a second film on the first film, the first film and the second film providing an opening exposing the underlying film, the second film comprising silicon; and (b) removing the second film by plasma generated from a process gas without supplying an electrical bias to the substrate support or by supplying an electrical bias having a level of 200 W or less, or 1 kV or less to the substrate support, the plasma comprising a hydrogen fluoride etchant.

### CROSS-REFERENCE TO RELATED APPLICATIONS

This application is a continuation application of PCT Application No. PCT/JP2024/036324, filed on Oct. 10, 2024, which claims the benefit of priority from Japanese Patent Application No. 2023-182378, filed on Oct. 24, 2023. The entire contents of the above listed PCT and priority applications are incorporated herein by reference.

### BACKGROUND

### FIELD

Example embodiments of the present disclosure relate to a plasma processing method and a plasma processing apparatus.

### Description of the Related Art

Japanese Unexamined Patent Publication No. 2015-12178 discloses a plasma etching method including a first step, a second step, and a third step. In the first step, a photoresist film having a pattern formed on a mask film is plasma-processed. In the second step, the mask film is etched by plasma along the pattern of the plasma-processed photoresist film to expose an organic film formed under the mask film. In the third step, the organic film is etched by plasma of a mixed gas containing O₂, COS, and Cl₂.

### SUMMARY

In one example embodiment, a plasma processing method includes (a) providing a substrate on a substrate support in a chamber, the substrate having an underlying film, a first film on the underlying film, and a second film on the first film, the first film and the second film providing an opening exposing the underlying film, the second film comprising silicon; and (b) removing the second film by plasma generated from a process gas without supplying an electrical bias to the substrate support or by supplying an electrical bias having a level of 200 W or less, or 1 kV or less to the substrate support, the plasma comprising a hydrogen fluoride etchant.

### BRIEF DESCRIPTION OF THE DRAWINGS

FIG. 1 is a diagram for explaining a configuration example of a plasma processing system.

FIG. 2 is a diagram for explaining a configuration example of an inductively coupled plasma processing apparatus.

FIG. 3 is a flowchart of a plasma processing method according to one example embodiment.

FIG. 4 is a partially enlarged view of an example substrate to which the method of FIG. 3 can be applied.

FIG. 5 is a cross-sectional view illustrating a step of a plasma processing method according to one example embodiment.

FIG. 6 is a cross-sectional view illustrating a step of a plasma processing method according to one example embodiment.

FIG. 7 is a cross-sectional view illustrating a step of a plasma processing method according to one example embodiment.

FIG. 8 is a cross-sectional view illustrating a step of a plasma processing method according to one example embodiment.

### DETAILED DESCRIPTION

Hereinafter, embodiments of the present disclosure will be described in detail with reference to the accompanying drawings. In the description of the drawings, the same reference numerals are used for the same or equivalent elements, and duplicate descriptions are omitted.

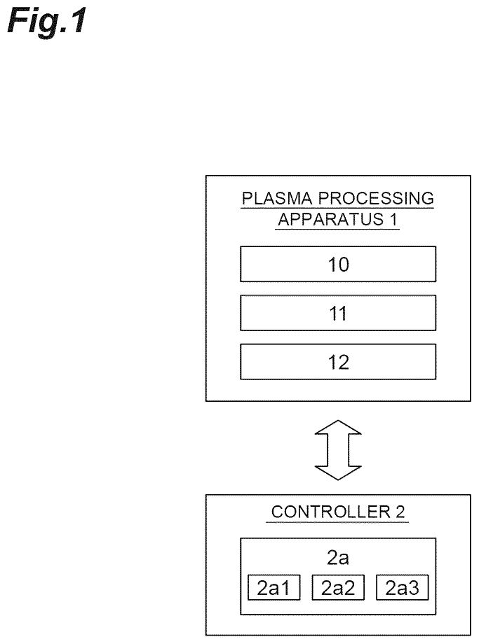

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

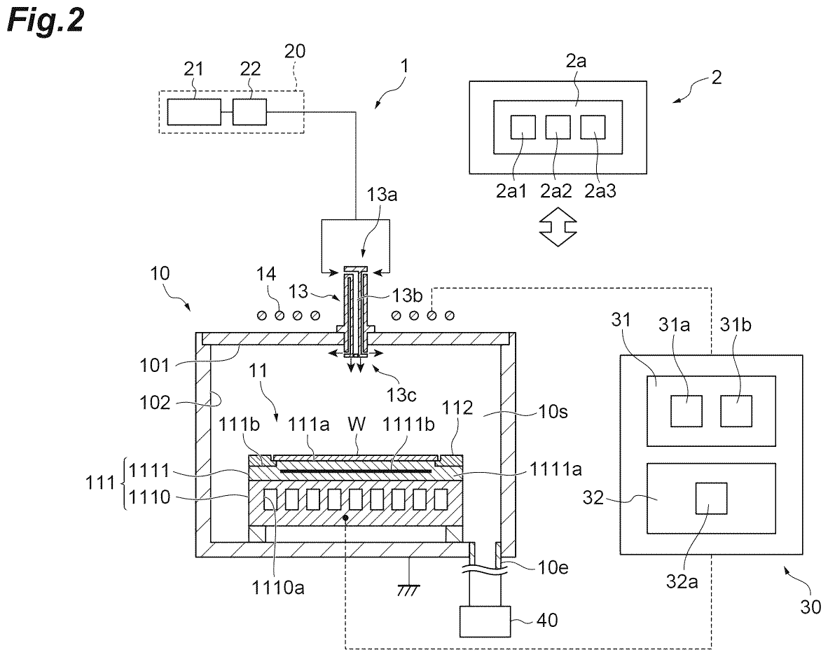

An example configuration of an inductively coupled plasma processing apparatus, which is an example of the plasma processing apparatus 1, will now be described. FIG. 2 illustrates the example configuration of the inductively coupled plasma processing apparatus.

The inductively coupled plasma processing apparatus 1 includes a plasma processing chamber 10, a gas supply 20, an electric power source 30, and a gas exhaust system 40. The plasma processing chamber 10 includes a dielectric window 101. The plasma processing apparatus 1 includes a substrate support 11, a gas introduction unit, and an antenna 14. The substrate support 11 is disposed in the plasma processing chamber 10. The antenna 14 is disposed on or above the plasma processing chamber 10 (i.e., on or above the dielectric window 101). The plasma processing chamber 10 has a plasma processing space 10s that is defined by the dielectric window 101, the sidewall 102 of the plasma processing chamber 10, and the substrate support 11. The plasma processing chamber 10 is grounded.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the annular electrostatic chuck 1111 and the annular insulating member. At least one RF/DC electrode coupled to a radio frequency (RF) source 31 and/or a direct current (DC) source 32 described below may be disposed in the ceramic member 1111a. In this case, the at least one RF/DC electrode functions as the bias electrode. It is noted that the conductive member of the base 1110 and the at least one RF/DC electrode may each function as a bias electrode. The electrostatic electrode 1111b may also function as a bias electrode. The substrate support 11 accordingly includes at least one bias electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The gas introduction unit is configured to introduce the at least one process gas from the gas supply 20 into the plasma processing space 10s. In an embodiment, the gas introduction unit includes a center gas injector (CGI) 13. The CGI 13 is disposed above the substrate support 11 and attached to a central opening formed in the dielectric window 101. The CGI 13 has at least one gas inlet 13a, at least one gas flow passage 13b, and at least one gas introduction port 13c. The process gas supplied to the gas inlet 13a flows through the gas flow passage 13b and is then introduced into the plasma processing space 10s from the gas introduction port 13c. The gas introduction unit may include one or more side gas injectors (SGIs) attached to one or more openings formed in the sidewall 102, in addition to or in place of the CGI 13.

The gas supply 20 may include at least one gas source 21 and at least one flow controller 22. In an embodiment, the gas supply 20 is configured to supply at least one process gas from the corresponding gas source 21 through the corresponding flow controller 22, into the gas introduction unit. Each flow controller 22 may be, for example, a mass flow controller or pressure-controlled flow controller. The gas supply 20 may include one or more flow modulation devices that can modulate or pulse the flow of the at least one process gas.

The electric power source 30 includes an RF source 31 coupled to the plasma processing chamber 10 through at least one impedance matching circuit. The RF source 31 is configured to supply at least one RF signal (RF power) to at least one bias electrode and/or the antenna 14. A plasma is thereby formed from at least one process gas supplied into the plasma processing space 10s. Thus, the RF source 31 can function as at least part of the plasma generator 12. The bias RF signal supplied to the at least one bias electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the antenna 14 through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the antenna 14.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsated.

The electric power source 30 may also include a DC source 32 coupled to the plasma processing chamber 10. The DC source 32 includes a bias DC generator 32a. In an embodiment, the bias DC generator 32a is connected to at least one bias electrode and is configured to generate a bias DC signal. The resulting bias DC signal is applied to the at least one bias electrode.

In various embodiments, the bias DC signal may be a pulsed. In this case, a sequence of voltage pulses is applied to the at least one bias electrode. The voltage pulses have rectangular, trapezoidal, or triangular waveform, or a combined waveform thereof. In an embodiment, a waveform generator for generating a sequence of voltage pulses from the DC signal is disposed between the bias DC generator 32a and the at least one bias electrode. The bias DC generator 32a and the waveform generator thereby functions as a voltage pulse generator. The voltage pulse may have positive polarity or negative polarity. A sequence of voltage pulses may also include one or more positive voltage pulses and one or more negative voltage pulses in a cycle. The bias DC generator 32a may be disposed in addition to the RF power source 31, or the bias DC generator 32a may be disposed in place of the second RF generator 31b.

The antenna 14 includes one or more coils. In an embodiment, the antenna 14 may include an outer coil and an inner coil that are coaxially disposed. In this case, the RF source 31 may be connected to both the outer coil and the inner coil, or either the outer coil or the inner coil. In the former case, a single RF generator may be connected to the outer and inner coils, or different RF generators may be connected to the outer and inner coils, respectively.

The gas exhaust system 40 may be connected to, for example, the gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

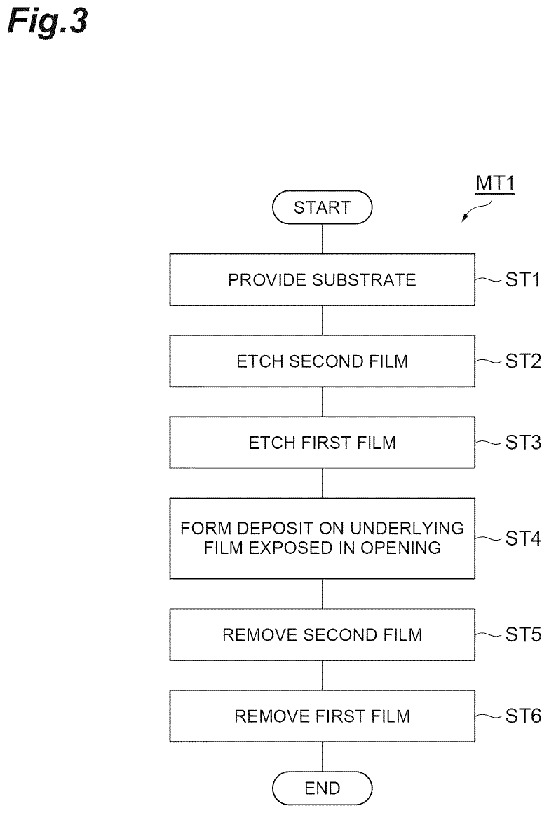

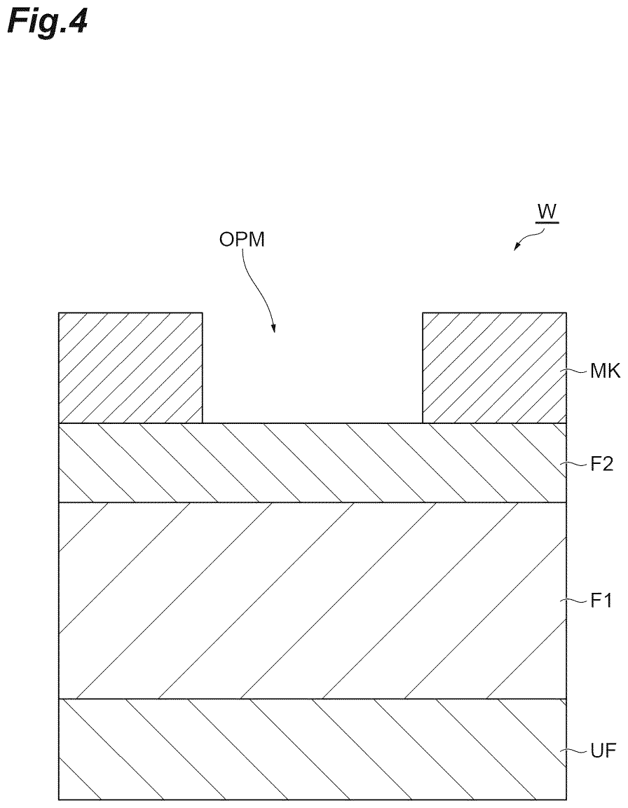

FIG. 3 is a flowchart of a plasma processing method according to one example embodiment. A plasma processing method MT1 illustrated in FIG. 3 (hereinafter referred to as “method MT1”) can be executed by the plasma processing apparatus 1 of the above embodiment. The method MT1 can be applied to the substrate W of FIG. 4.

FIG. 4 is a cross-sectional view of an example substrate to which the method of FIG. 3 can be applied. As illustrated in FIG. 4, in one embodiment, the substrate W has an underlying film UF, a first film F1 on the underlying film UF, and a second film F2 on the first film F1. The underlying film UF, the first film F1, and the second film F2 may comprise different materials from each other.

The first film F1 may be a carbon-containing film or a metal-containing film. The carbon-containing film may include at least one selected from the group consisting of spin-on carbon and amorphous carbon. The metal-containing film may include at least one selected from the group consisting of aluminum oxide (Al₂O₃), titanium nitride (TiN), tungsten carbide (WC), and zirconium oxide (ZrO₂). The first film F1 may not comprise silicon.

The second film F2 comprises silicon. That is, the second film F2 is a silicon-containing film. The silicon-containing film may include at least one selected from the group consisting of silicon oxynitride (SiON), spin on glass (SOG), silicon oxide (SiO₂), silicon carbide (SiC), and silicon nitride (SiN).

The underlying film UF may be a metal-containing film or may be a silicon-containing film. Examples of the metal-containing film and the silicon-containing film may be the same as the examples in the first film F1 or the second film F2. The underlying film UF may be a silicon-containing film of a different type from the second film F2. The underlying film UF may be a metal-containing film of a different type from the first film F1.

The substrate W may further have a mask MK on the second film F2. The mask MK may include a photoresist. The mask MK may have at least one opening OPM. A pitch of the opening OPM may be 80 nm or less. The pitch of the opening OPM can be measured at an upper end of the opening OPM (an upper surface of the mask MK).

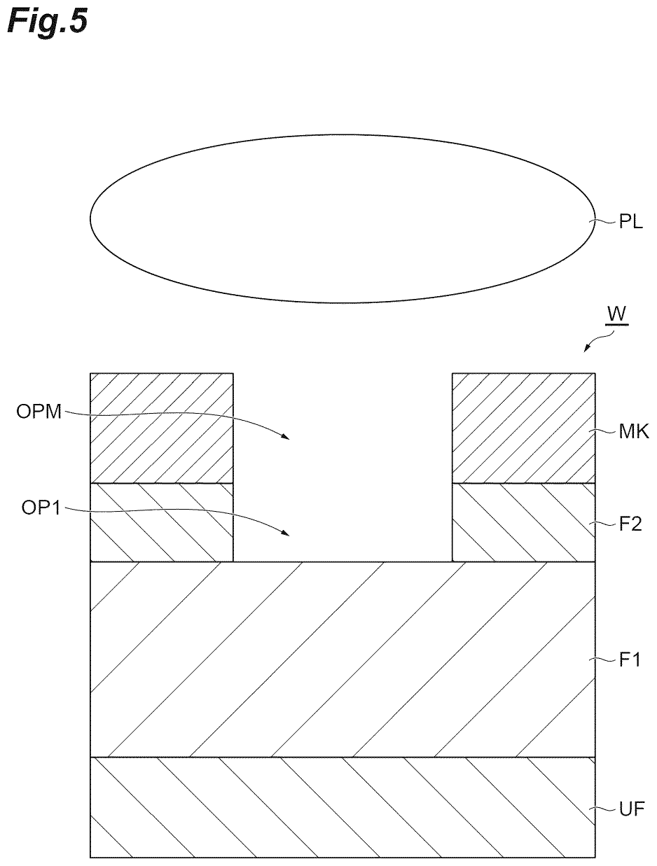

Hereinafter, the method MT1 will be described with reference to FIGS. 3 to 8, taking as an example a case where the method MT1 is applied to the substrate W using the plasma processing apparatus 1 of the above embodiment. FIGS. 5 to 8 are cross-sectional views illustrating steps of a plasma processing method according to one example embodiment. When the plasma processing apparatus 1 is used, the method MT1 can be executed in the plasma processing apparatus 1 through control of each part of the plasma processing apparatus 1 by the controller 2. In the method MT1, as illustrated in FIG. 2, the substrate W on the substrate support 11 disposed in the plasma processing chamber 10 is processed.

As illustrated in FIG. 3, the method MT1 may include steps ST1 to ST6. Steps ST1 to ST6 can be executed in order. Step ST4 may be performed before step ST5 or may be performed simultaneously with step ST5. The method MT1 may not include at least one of steps ST2 to ST4 and step ST6.

### Step ST1

In step ST1, the substrate W illustrated in FIG. 4 is provided on the substrate support 11 in the plasma processing chamber 10.

### Step ST2

In step ST2, as illustrated in FIG. 5, the second film F2 is etched through the opening OPM of the mask MK by plasma PL generated from a process gas to form a first opening OP1 in the second film F2. The first opening OP1 corresponds to the opening OPM. The first opening OP1 exposes the first film F1.

Step ST2 may be performed as follows. The gas supply 20 supplies the process gas into the plasma processing chamber 10. The controller 2 controls the gas supply 20 and the plasma generator 12 to generate plasma PL from the process gas.

### Step ST3

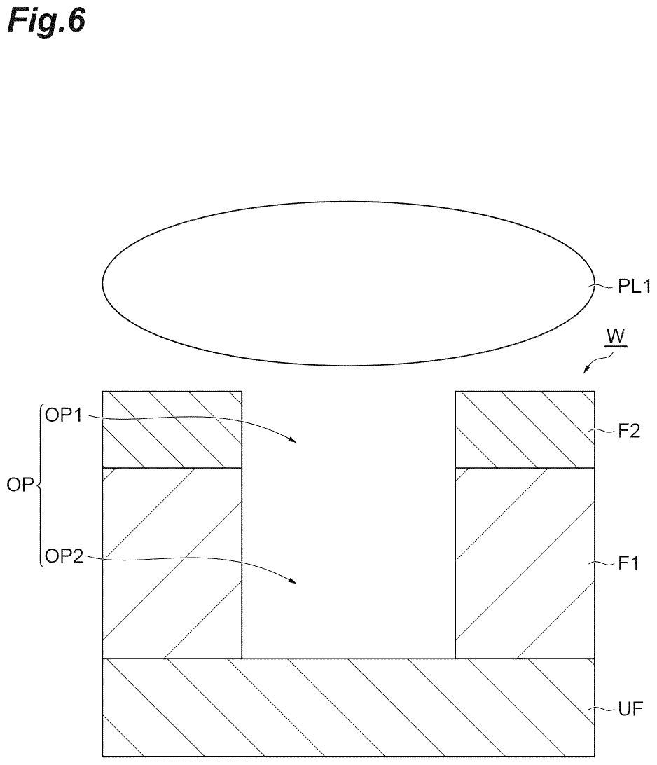

In step ST3, as illustrated in FIG. 6, the first film F1 is etched by a first plasma PL1 generated from a first process gas to form a second opening OP2 in the first film F1. The second opening OP2 corresponds to the first opening OP1. An opening OP including the first opening OP1 and the second opening OP2 exposes the underlying film UF. That is, the first film F1 and the second film F2 provide the opening OP exposing the underlying film UF. A pitch of the opening OP may be 80 nm or less. The pitch of the opening OP can be measured at an upper end of the opening OP (an upper surface of the second film F2). When the method MT1 does not include steps ST2 to ST4, the substrate W illustrated in FIG. 6 may be provided on the substrate support 11 in step ST1. When the method MT1 does not include steps ST2 and ST4, the substrate W illustrated in FIG. 5 may be provided on the substrate support 11 in step ST1.

Step ST3 may be performed as follows. The gas supply 20 supplies the first process gas into the plasma processing chamber 10. The controller 2 controls the gas supply 20 and the plasma generator 12 to generate the first plasma PL1 from the first process gas.

### Step ST4

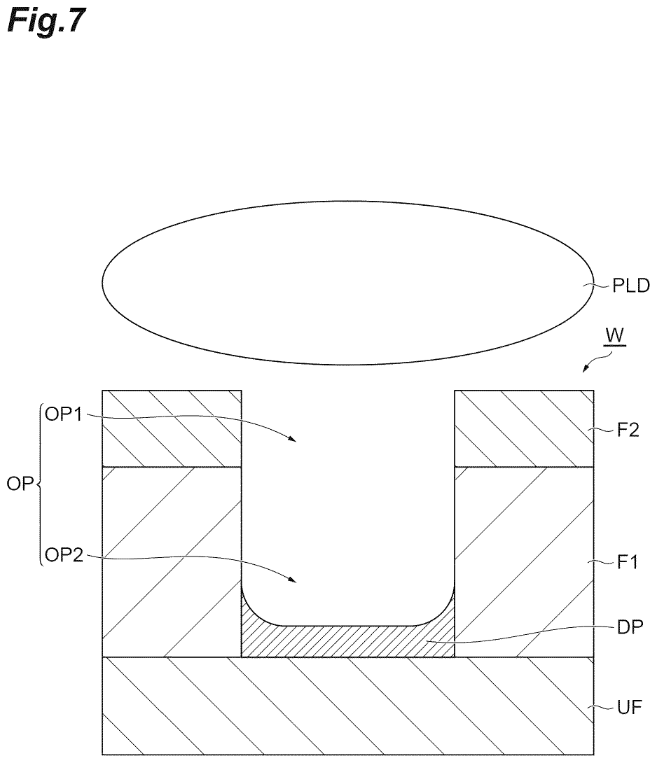

In step ST4, as illustrated in FIG. 7, a deposit DP is formed on the underlying film UF exposed in the opening OP. The deposit DP may be formed by plasma PLD. The plasma PLD may be generated from a process gas comprising a hydrogen halide gas and a carbon-containing gas without supplying an electrical bias to the substrate support 11. The hydrogen halide gas may be hydrogen fluoride (HF) gas, hydrogen chloride (HCl) gas, or hydrogen bromide (HBr) gas. The carbon-containing gas may be a hydrocarbon (CₓH_{y}) gas, a fluorocarbon (CₓF_{y}) gas, or a hydrofluorocarbon (CₓH_{y}F_{z}) gas. Each of x, y, and z is a positive real number. The deposit DP may comprise carbon. The deposit DP may be formed by a flowable carbon-containing substance moving on a sidewall of the opening OP and accumulating on the underlying film UF.

Step ST4 may be performed as follows. The gas supply 20 supplies the process gas into the plasma processing chamber 10. The controller 2 controls the gas supply 20 and the plasma generator 12 to generate plasma PLD from the process gas.

### Step ST5

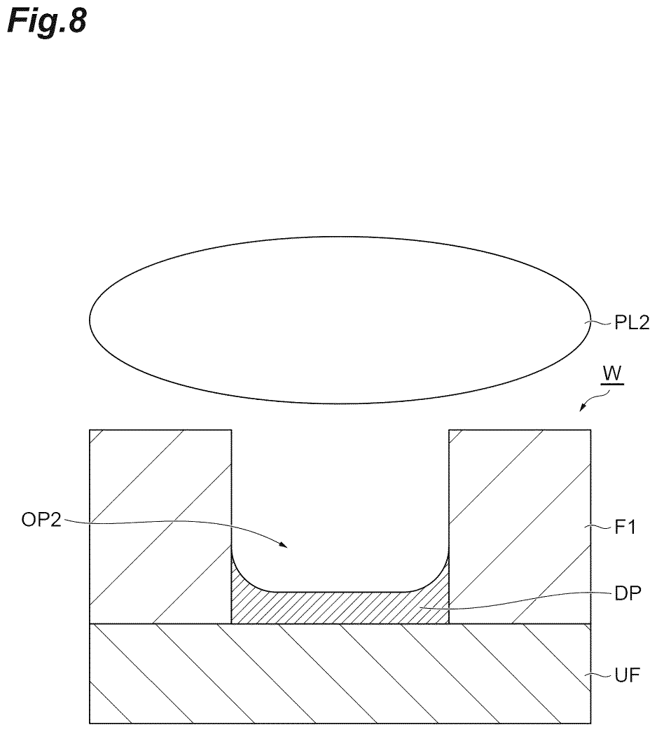

In step ST5, as illustrated in FIG. 8, the second film F2 is removed by a second plasma PL2 generated from a second process gas. The second plasma PL2 comprises a hydrogen fluoride etchant (HF etchant). At the end of step ST5, the deposit DP may remain on the underlying film UF. The hydrogen fluoride etchant etches the second film F2, which is a silicon-containing film. The hydrogen fluoride etchant may include hydrogen fluoride active species and neutral molecules of hydrogen fluoride. The hydrogen fluoride active species may include hydrogen fluoride ions and hydrogen fluoride radicals. In the second plasma PL2, H—F bonds are less likely to dissociate, so a hydrogen fluoride etchant having H—F bonds is generated.

In step ST5, the second process gas may comprise hydrogen and fluorine. The second process gas may include at least one selected from the group consisting of a mixed gas comprising a hydrogen-containing gas and a fluorine-containing gas; a hydrogen fluoride gas; and a hydrofluorocarbon gas. The hydrogen-containing gas may be, for example, H₂ gas, NH₃ gas, H₂O gas, H₂O₂ gas, or a hydrocarbon (CH₄ gas, C₃H₆ gas, etc.). The fluorine-containing gas may be NF₃ gas, SF₆ gas, WF₆ gas, XeF₂ gas, a fluorocarbon, or a hydrofluorocarbon. In one example, the mixed gas comprising hydrogen and fluorine may include H₂ gas and CF₄ gas. The hydrofluorocarbon gas may be at least one selected from the group consisting of CHF₃, CH₂F₂, CH₃F, C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀, c-C₅H₃F₇, and C₃H₂F₄.

In step ST5, the second process gas may further include at least one selected from the group consisting of an inert gas, a fluorocarbon gas (CₓF_{y} gas), and a phosphorus-containing gas. The inert gas may be a noble gas or nitrogen (N₂) gas. An example of the noble gas includes argon gas. The fluorocarbon gas may be at least one selected from the group consisting of CF₄, C₂F₂, C₂F₄, C₃F₈, C₄F₆, C₄F₈, and C₅F₈. The phosphorus-containing gas may include at least one selected from the group consisting of phosphorus trifluoride gas (PF₃ gas), phosphorus pentafluoride gas (PF₅ gas), phosphorus trichloride gas (PCl₃ gas), phosphorus pentachloride gas (PCl₅ gas), phosphorus tribromide gas (PBr₃ gas), phosphorus pentabromide gas (PBr₅ gas), and phosphorus iodide gas (PI₃ gas).

In step ST5, the second process gas may not comprise a carbon-containing gas. Among all gases comprised in the second process gas, excluding noble gases, a flow rate of hydrogen fluoride gas may be the largest. A ratio of a total flow rate of fluorocarbon gas and hydrofluorocarbon gas to a total flow rate of the second process gas may be 0.1 or less. A ratio of a flow rate of phosphorus-containing gas to a total flow rate of the second process gas may be 0.1 or less.

In step ST5, an electrical bias may not be supplied to the substrate support 11, or an electrical bias having a level smaller than a level of the electrical bias supplied to the substrate support 11 in step ST3 may be supplied to the substrate support 11. In step ST5, an electrical bias may not be supplied to the substrate support 11, or an electrical bias having a level of 200 W or less, or 1 kV or less may be supplied to the substrate support 11.

The electrical bias may be bias RF power. In this case, the level of the electrical bias is a power level (effective value) of the bias RF power. The level of the electrical bias may be 200 W or less, may be 100 W or less, or may be 50 W or less.

The electrical bias may be a direct current (DC) voltage. The DC voltage may include voltage pulses. In this case, the level of the electrical bias is an absolute value of a voltage level of the voltage pulse. The level of the electrical bias may be 1 kV or less, may be 500 V or less, or may be 100 V or less.

In step ST5, an electrical bias may be supplied to the substrate support 11. In this case, ion energy generated from the second plasma PL2 and incident on the substrate W may be 500 eV or less. The ion energy in the present disclosure may be an average ion energy incident on an upper surface of the substrate. The average ion energy may be calculated, for example, from process conditions and a magnitude of the electrical bias supplied to the substrate support 11 (a power level of bias RF power, a voltage level of voltage pulses), or may be calculated based on simulation results.

In step ST5, a temperature of the substrate support 11 may be 60° C. or less, or may be 30° C. or less. In step ST5, a pressure in the plasma processing chamber 10 may be 6.67 Pa (50 mTorr) or more or may be 13.3 Pa (100 mTorr) or more.

Step ST5 may include a first period and a second period alternating with the first period. The first period and the second period are alternately arranged. In the first period, a first source RF signal for generating the second plasma PL2 is supplied. The first source RF signal has a first level. In the second period, no source RF signal is supplied, or a second source RF signal having a second level smaller than the first level is supplied.

Step ST5 may be performed as follows. The gas supply 20 supplies the second process gas into the plasma processing chamber 10. The controller 2 controls the gas supply 20 and the plasma generator 12 to generate the second plasma PL2 from the second process gas.

After step ST5, the underlying film UF may be etched by plasma generated from a process gas. In this case, an opening corresponding to the second opening OP2 of the first film F1 is formed in the underlying film UF. When the deposit DP remains on the underlying film UF at the end of step ST5, the underlying film UF is etched after the deposit DP is removed by plasma generated from a process gas.

### Step ST6

In step ST6, the first film F1 is removed in the plasma processing chamber 10. The first film F1 may be removed by plasma generated from a process gas comprising an oxygen-containing gas. The oxygen-containing gas may be oxygen (O₂) gas. Step ST6 may be performed in the same plasma processing chamber 10 as step ST5 or may be performed subsequently to step ST5.

According to the method MT1, in step ST5, the silicon-containing film (second film F2) can be selectively removed with respect to other films (first film F1). The hydrogen fluoride etchant comprised in the second plasma PL2 reacts more easily with the silicon-containing film than with other films. As a result, an etching rate of the first film F1 is smaller than an etching rate of the second film F2.

Furthermore, according to the method MT1, since etching of the first film F1 can be suppressed, etching of a sidewall defining the second opening OP2 of the first film F1 is suppressed. Therefore, occurrence of a shape abnormality (bowing) at the sidewall defining the second opening OP2 can be suppressed.

When the underlying film UF is a metal-containing film, in step ST5, the hydrogen fluoride etchant comprised in the second plasma PL2 is less likely to etch the underlying film UF. Therefore, metal residue is unlikely to be generated from the underlying film UF.

When the method MT1 includes step ST4, the underlying film UF is protected by the deposit DP in step ST5. Therefore, even when the underlying film UF is a silicon-containing film, an etching selectivity of the second film F2 with respect to the underlying film UF can be improved.

When the pressure in the plasma processing chamber 10 is 6.67 Pa or more in step ST5, an etching selectivity of the second film F2 with respect to the first film F1 can be improved in step ST5.

Hereinafter, various experiments conducted for evaluation of the method MT1 will be described. The experiments described below do not limit the present disclosure.

### First Experiment

In the first experiment, first, a substrate was provided on a substrate support in a chamber of a plasma processing apparatus. The substrate has a structure similar to the substrate W illustrated in FIG. 6. The substrate has a silicon oxide film, an amorphous carbon film on the silicon oxide film, and a SiON film on the amorphous carbon film. The amorphous carbon film and the SiON film provide an opening exposing the silicon oxide film.

Next, without supplying an electrical bias to the substrate support, plasma was generated from a process gas comprising hydrogen fluoride gas and argon gas, and the SiON film was removed by the plasma. A temperature of the substrate support was 0° C. A pressure in the chamber was 66.7 Pa. A power level of source RF power for generating plasma was 1000 W.

### Second Experiment

An experiment was conducted in the same manner as the first experiment except that the temperature of the substrate support was set to 30° C.

### Third Experiment

An experiment was conducted in the same manner as the first experiment except that the temperature of the substrate support was set to 60° C.

### First Experimental Results

In each of the first to third experiments, a cross section of the substrate was observed. In the first to third experiments, the SiON film was removed. In the first to third experiments, no shape abnormality (bowing) was observed at the sidewall defining the opening of the amorphous carbon film.

### Fourth Experiment

In the fourth experiment, a substrate was provided on a substrate support in the same manner as in the first experiment.

Next, without supplying an electrical bias to the substrate support, plasma was generated from a process gas comprising hydrogen fluoride gas, CH₃F gas, and argon gas, and the SiON film was removed by the plasma. A temperature of the substrate support was 0° C. A pressure in the chamber was 1.33 Pa. A power level of source RF power for generating plasma was 2000 W.

### Fifth Experiment

An experiment was conducted in the same manner as the fourth experiment except that the pressure in the chamber was set to 13.3 Pa.

### Sixth Experiment

An experiment was conducted in the same manner as the fourth experiment except that a process gas comprising nitrogen gas instead of argon gas was used, the temperature of the substrate support was set to 60° C., and the pressure in the chamber was set to 13.3 Pa.

### Seventh Experiment

An experiment was conducted in the same manner as the fourth experiment except that a process gas comprising C₄F₆ gas instead of CH₃F gas was used.

### Eighth Experiment

An experiment was conducted in the same manner as the seventh experiment except that the pressure in the chamber was set to 13.3 Pa.

### Ninth Experiment

An experiment was conducted in the same manner as the seventh experiment except that the temperature of the substrate support was set to 60° C. and the power level of source RF power was set to 250 W.

### Tenth Experiment

An experiment was conducted in the same manner as the seventh experiment except that the temperature of the substrate support was set to 60° C., the power level of source RF power was set to 250 W, and the pressure in the chamber was set to 13.3 Pa.

### Eleventh Experiment

An experiment was conducted in the same manner as the seventh experiment except that a process gas comprising nitrogen gas instead of argon gas was used and the pressure in the chamber was set to 13.3 Pa.

### Second Experimental Results

In each of the fourth to eleventh experiments, a cross section of the substrate was observed. In the fourth to eleventh experiments, a deposit was formed on the silicon oxide film exposed in the opening of the amorphous carbon film (see FIG. 7).

Although various example embodiments have been described above, various additions, omissions, substitutions, and changes may be made without being limited to the example embodiments described above. It is also possible to combine elements in different embodiments to form other embodiments.

Here, various example embodiments included in the present disclosure are described in [E1] to [E19] below.

### [E1]

A plasma processing method comprising:
(a) providing a substrate on a substrate support in a chamber, the substrate having an underlying film, a first film on the underlying film, and a second film on the first film, the first film and the second film providing an opening exposing the underlying film, the second film comprising silicon; and
(b) removing the second film by plasma generated from a process gas without supplying an electrical bias to the substrate support or by supplying an electrical bias having a level of 200 W or less, or 1 kV or less to the substrate support, the plasma comprising a hydrogen fluoride etchant.

According to the plasma processing method [E1], the second film can be selectively removed with respect to the first film.

### [E2]

The plasma processing method according to [E1], wherein the process gas comprises hydrogen fluoride gas.

### [E3]

The plasma processing method according to [E1] or [E2], wherein the first film is a carbon-containing film or a metal-containing film.

### [E4]

The plasma processing method according to any one of [E1] to [E3], wherein the underlying film is a metal-containing film.

In this case, since the underlying film is less likely to etch in (b), metal residue is unlikely to be generated from the underlying film.

### [E5]

The plasma processing method according to any one of [E1] to [E3], wherein the underlying film is a silicon-containing film.

### [E6]

The plasma processing method according to any one of [E1] to [E5], wherein the process gas further comprises at least one selected from the group consisting of an inert gas, a fluorocarbon gas, a hydrofluorocarbon gas, and a phosphorus-containing gas.

### [E7]

The plasma processing method according to any one of [E1] to [E6], further comprising (c) forming a deposit on the underlying film exposed in the opening.

In this case, the underlying film is less likely to etch in (b).

### [E8]

The plasma processing method according to [E7], wherein in the (c), plasma is generated from a process gas comprising a hydrogen halide gas and a carbon-containing gas without supplying the electrical bias to the substrate support.

### [E9]

The plasma processing method according to [E8], wherein the hydrogen halide gas is hydrogen fluoride gas, hydrogen chloride gas, or hydrogen bromide gas.

### [E10]

The plasma processing method according to [E8] or [E9], wherein the carbon-containing gas is a hydrocarbon gas, a fluorocarbon gas, or a hydrofluorocarbon gas.

### [E11]

The plasma processing method according to any one of [E1] to [E10], wherein in the (b), a temperature of the substrate support is 30° C. or less.

### [E12]

The plasma processing method according to any one of [E1] to [E 11], wherein in the (b), a pressure in the chamber is 6.67 Pa or more.

In this case, in (b), an etching selectivity of the second film with respect to the first film can be improved.

### [E13]

A plasma processing method comprising:
(a) providing a substrate on a substrate support in a chamber, the substrate having an underlying film, a first film on the underlying film, and a second film on the first film, the second film having a first opening exposing the first film, the second film comprising silicon;
(b) etching the first film by a first plasma generated from a first process gas to form a second opening in the first film; and
(c) removing the second film by a second plasma generated from a second process gas, the second plasma comprising a hydrogen fluoride etchant,
wherein in the (c), an electrical bias is not supplied to the substrate support, or an electrical bias having a level smaller than a level of the electrical bias supplied to the substrate support in the (b) is supplied to the substrate support.

### [E14]

The plasma processing method according to any one of [E1] to [E12], wherein the (b) includes:
a first period in which a first source RF signal for generating the plasma is supplied, the first source RF signal having a first level; and
a second period alternating with the first period, wherein in the second period, no source RF signal is supplied or a second source RF signal having a second level smaller than the first level is supplied.

### [E15]

A plasma processing method comprising:
(a) providing a substrate on a substrate support in a chamber, the substrate having an underlying film, a first film on the underlying film, and a second film on the first film, the first film and the second film providing an opening exposing the underlying film, the second film comprising silicon; and
(b) removing the second film by plasma generated from a process gas by supplying an electrical bias to the substrate support, the plasma comprising a hydrogen fluoride etchant, ion energy generated from the plasma and incident on the substrate being 500 eV or less.

### [E16]

The plasma processing method according to [E15],
wherein the first film is a carbon-containing film, and
the underlying film is a metal-containing film.

### [E17]

The plasma processing method according to [E15] or [E16], further comprising (c) removing the first film in the chamber after the (b).

### [E18]

The plasma processing method according to any one of [E1] to [E17], wherein a pitch of the opening is 80 nm or less.

### [E19]

A plasma processing apparatus comprising:
a chamber;
a substrate support for supporting a substrate in the chamber, the substrate having an underlying film, a first film on the underlying film, and a second film on the first film, the first film and the second film providing an opening exposing the underlying film, the second film comprising silicon;
a gas supply configured to supply a process gas into the chamber;
a plasma generator configured to generate plasma from the process gas in the chamber, the plasma comprising a hydrogen fluoride etchant; and
a circuitry configured to control the plasma processing apparatus to execute a plasma processing method, the plasma processing method including:
(b) removing the second film by the plasma without supplying an electrical bias to the substrate support or by supplying an electrical bias having a level of 200 W or less, or 1 kV or less to the substrate support.

According to one example embodiment, a technique capable of selectively removing a silicon-containing film with respect to other films is provided.

From the above description, it will be understood that various embodiments of the present disclosure have been described in the present specification for purposes of illustration, and that various modifications may be made without departing from the scope and spirit of the present disclosure. Accordingly, the various embodiments disclosed in the present specification are not intended to be limiting, with the true scope and spirit being indicated by the following claims.

What is claimed is:

1. A plasma processing method comprising:
providing a substrate on a substrate support in a chamber, the substrate having an underlying film, a first film on the underlying film, and a second film on the first film, the first film and the second film defining an opening exposing the underlying film, the second film comprising silicon; and
removing the second film by plasma generated from a process gas without supplying an electrical bias to the substrate support or by supplying an electrical bias having a level of 200 W or less, or 1 kV or less to the substrate support, the plasma comprising a hydrogen fluoride etchant.

2. The plasma processing method according to claim 1, wherein
the process gas comprises hydrogen fluoride gas.

3. The plasma processing method according to claim 1, wherein
the first film is a carbon-containing film or a metal-containing film.

4. The plasma processing method according to claim 1, wherein
the underlying film is a metal-containing film.

5. The plasma processing method according to claim 1, wherein
the underlying film is a silicon-containing film.

6. The plasma processing method according to claim 1, wherein
the process gas further comprises at least one selected from the group consisting of an inert gas, a fluorocarbon gas, a hydrofluorocarbon gas, and a phosphorus-containing gas.

7. The plasma processing method according to claim 1, further comprising:
forming a deposit on the underlying film exposed in the opening.

8. The plasma processing method according to claim 7, wherein
in the forming a deposit, plasma is generated from a process gas comprising a hydrogen halide gas and a carbon-containing gas without supplying the electrical bias to the substrate support.

9. The plasma processing method according to claim 8, wherein
the hydrogen halide gas is hydrogen fluoride gas, hydrogen chloride gas, or hydrogen bromide gas.

10. The plasma processing method according to claim 8, wherein
the carbon-containing gas is a hydrocarbon gas, a fluorocarbon gas, or a hydrofluorocarbon gas.

11. The plasma processing method according to claim 1, wherein
in the removing the second film, a temperature of the substrate support is 30° C. or less.

12. The plasma processing method according to claim 1, wherein
in the removing the second film, a pressure in the chamber is 6.67 Pa or more.

13. A plasma processing method comprising:
providing a substrate on a substrate support in a chamber, the substrate having an underlying film, a first film on the underlying film, and a second film on the first film, the second film having a first opening exposing the first film, the second film comprising silicon;
etching the first film by a first plasma generated from a first process gas to form a second opening in the first film; and
removing the second film by a second plasma generated from a second process gas, the second plasma comprising a hydrogen fluoride etchant,
wherein in the removing the second film, an electrical bias is not supplied to the substrate support, or an electrical bias having a level smaller than a level of the electrical bias supplied to the substrate support in the etching the first film is supplied to the substrate support.

14. The plasma processing method according to claim 13, wherein
the etching the first film includes:
a first period in which a first source RF signal for generating the plasma is supplied, the first source RF signal having a first level; and
a second period alternating with the first period, wherein in the second period, no source RF signal is supplied or a second source RF signal having a second level smaller than the first level is supplied.

15. A plasma processing method comprising:
providing a substrate on a substrate support in a chamber, the substrate having an underlying film, a first film on the underlying film, and a second film on the first film, the first film and the second film defining an opening exposing the underlying film, the second film comprising silicon; and
removing the second film by plasma generated from a process gas by supplying an electrical bias to the substrate support, the plasma comprising a hydrogen fluoride etchant, ion energy generated from the plasma and incident on the substrate being 500 eV or less.

16. The plasma processing method according to claim 15, wherein
the first film is a carbon-containing film, and
the underlying film is a metal-containing film.

17. The plasma processing method according to claim 15, further comprising:
removing the first film in the chamber after the removing the second film.

18. The plasma processing method according to claim 15, wherein
a pitch of the opening is 80 nm or less.

19. A plasma processing apparatus comprising:
a chamber;
a substrate support configured to support a substrate in the chamber, the substrate having an underlying film, a first film on the underlying film, and a second film on the first film, the first film and the second film defining an opening exposing the underlying film, the second film comprising silicon;
a gas supply configured to supply a process gas into the chamber;
a plasma generator configured to generate plasma from the process gas in the chamber, the plasma comprising a hydrogen fluoride etchant; and
a circuitry configured to control the plasma processing apparatus to execute a plasma processing method, the plasma processing method including:
removing the second film by the plasma without supplying an electrical bias to the substrate support or by supplying an electrical bias having a level of 200 W or less, or 1 kV or less to the substrate support.
